(19) United States
(12) Patent Application Publication
(10) Pub. No.: US 2010/0252902 A1
(43) Pub. Date: Oct. 7, 2010

(54) SEMICONDUCTOR DEVICE AND IMAGING DEVICE USING THE SEMICONDUCTOR DEVICE

(75) Inventors: Kazumasa Tanida, Kawasaki-shi (JP); Kenji Takahashi, Tsukuba-shi (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/718,419

(22) Filed: Mar. 5, 2010

(30) Foreign Application Priority Data
Apr. 1, 2009 (JP) 2009-089449

(51) Int. Cl. H01L 31/14; H01L 31/0232

(52) U.S. Cl. 257/433; 257/435; 257/E31.097; 257/E31.121; 257/E31.127

(57) ABSTRACT

A semiconductor device, includes: a semiconductor substrate including a first surface and a second surface which are opposite to one another; a light receiving portion provided at the first surface of the semiconductor substrate; and an optical transparent protective member so as to cover and to be adjacent to the first surface or the second surface of the semiconductor substrate; wherein a plurality of depressed portions are formed at the optical transparent protective member so as to be opposite to the light receiving portion.

### CROSS-REFERENCE TO RELATED APPLICATIONS

This application is based upon and claims the benefit of priority from the prior Japanese Patent Application No. 2009-089449 filed on Apr. 1, 2009; the entire contents of which are incorporated herein by reference.

### BACKGROUND OF THE INVENTION

1. Field of the Invention

The present invention relates to a semiconductor device having a light-receiving element (light-receiving portion) and an imaging device using the semiconductor device.

2. Description of the Related Art

A semiconductor device such as a CCD or a CMOS image sensor using semiconductor integrated circuit technology is widely available for a digital camera and a cellular phone with a camera mechanism. In this case, in order to meet the downsizing and lightening of the parts to be mounted, it is proposed that a sensor chip (semiconductor chip) is configured as a CSP (Chip Size Package). In the CSP, some through-holes are formed to the main surface from the rear surface of the semiconductor chip constituting the sensor chip and the conductive layers are formed in the through-holes respectively to form the through-wiring layers therein. Then, external terminals are provided on the rear surface so as to be electrically connected with the through-wiring layers.

On the other hand, an integrated circuit containing a light receiving portion which is electrically connected with the through-wiring layers is provided on the main surface of the semiconductor chip and a color filter or a microlens array for concentration of light is provided over the light receiving portion. The thus obtained semiconductor device divided in chip form is mounted on a module board so as to be electrically connected with the module board, and a plastic case with an optical lens is mounted over the semiconductor device (chip) to form a camera module. In this case, in order to protect the light receiving portion from dirt and dust, an optical transparent protective member is formed so as to cover the light receiving portion.

In such a semiconductor device, conventionally, the through-wiring layers are formed by forming the corresponding through-holes through the etching for the semiconductor substrate from the rear surface to the main surface thereof and forming the corresponding conductive layers in the through-holes. In the formation of the through-wiring layers, on the other hand, the semiconductor substrate is thinned in advance such that the aspect ratios of the through-holes are reduced to simplify the formation of the through-wiring layers and to set the size of the semiconductor substrate to a size suitable for the CSP (Refer to Reference 1, for example).

[Reference 1] WO 2005/022631 A1

In the conventional semiconductor device manufactured as described above, however, a space with a larger area than the area of the light receiving portion is formed between the semiconductor substrate and the optical transparent protective member so as to accommodate the microlens array. Therefore, when the semiconductor substrate is thinned, the semiconductor substrate is bended toward the optical transparent protective member, causing the creation of crack in the semiconductor substrate and thus, the deterioration of manufacturing yield.

### BRIEF SUMMARY OF THE INVENTION

An aspect of the present invention relates to a semiconductor device, including: a semiconductor substrate including a first surface and a second surface which are opposite to one another; a light receiving portion provided at the first surface of the semiconductor substrate; and an optical transparent protective member so as to cover and to be adjacent to the first surface or the second surface of the semiconductor substrate; wherein a plurality of depressed portions are formed at the optical transparent protective member so as to be opposite to the light receiving portion (first semiconductor device).

Another aspect of the present invention relates to a semiconductor device, including: a semiconductor substrate including a first surface and a second surface which are opposite to one another; a light receiving portion provided at the first surface of the semiconductor substrate; an optical transparent protective member so as to cover the first surface of the semiconductor substrate; and a film formed between the first surface of the semiconductor substrate and the optical transparent protective member so as to be adjacent to the first surface and the optical transparent protective member; wherein a plurality of depressed portions are formed at the film so as to be opposite to the light receiving portion (second semiconductor device).

Still another aspect of the present invention relates to an imaging device, including: the second semiconductor device; a lens module provided on the optical transparent protective member of the semiconductor device; and a packaging board where the semiconductor device is mounted via external terminals.

### BRIEF DESCRIPTION OF THE DRAWINGS

FIG. 1 is a cross sectional view showing a semiconductor device according to a first embodiment.

FIG. 2 is an explanatory view about the concentration of light in the semiconductor device according to the first embodiment.

FIG. 3 relates to process views for explaining the manufacturing method of the semiconductor device according to the first embodiment.

FIG. 4 relates to process views for explaining the manufacturing method of the semiconductor device according to the first embodiment.

FIG. 5 is a cross sectional view showing a semiconductor device according to a second embodiment.

FIG. 6 is a cross sectional view showing a semiconductor device according to a third embodiment.

FIG. 7 relates to process views for explaining the manufacturing method of the semiconductor device according to the third embodiment.

FIG. 8 relates to process views for explaining the manufacturing method of the semiconductor device according to the third embodiment.

FIG. 9 relates to process views for explaining the manufacturing method of the semiconductor device according to the third embodiment.

FIG. 10 is a cross sectional view schematically showing an imaging device according to a fourth embodiment.

FIG. 11 is a cross sectional view of an imaging device modified from the imaging device shown in FIG. 10.

FIG. 12 is a cross sectional view of an imaging device modified from the imaging device shown in FIG. 10.

### DETAILED DESCRIPTION OF THE INVENTION

Then, some embodiments will be described with reference to the drawings. Herein, the drawings are provided for illustration, but the present invention is not limited to the drawings.

### First Embodiment

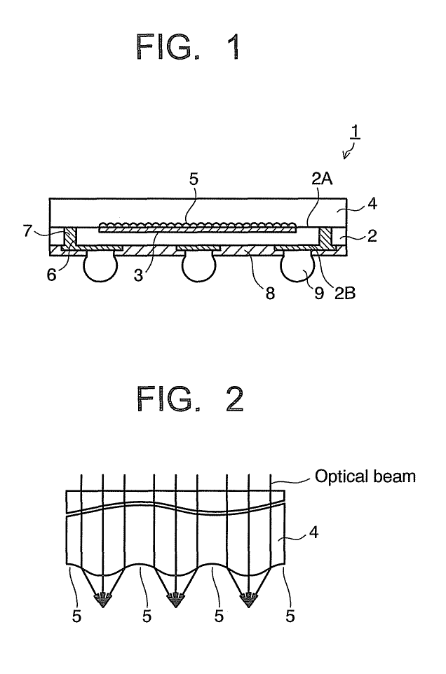

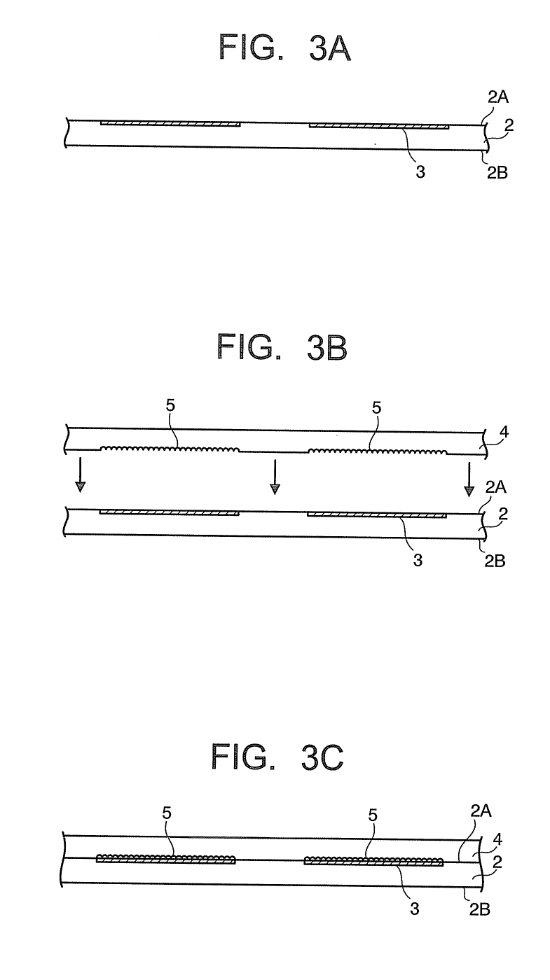

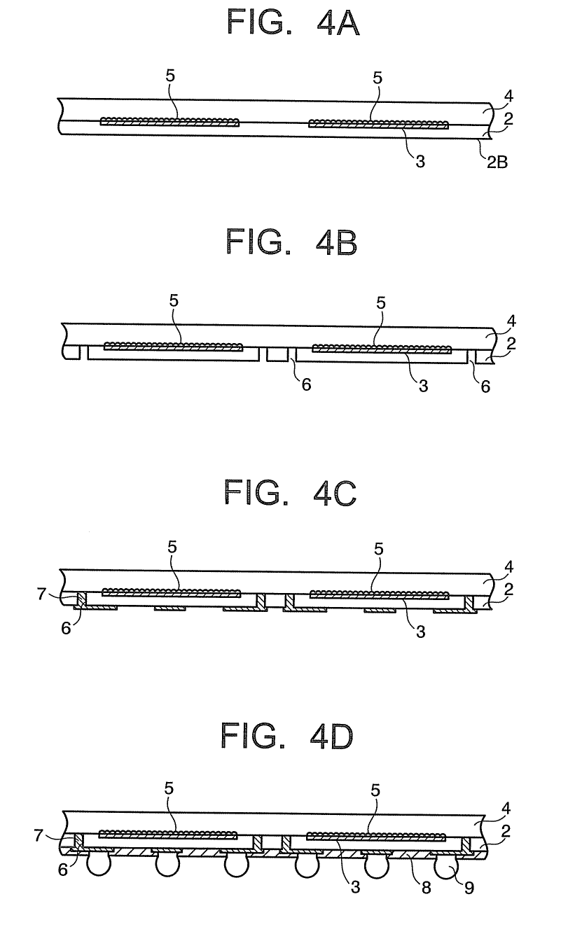

FIG. 1 is a cross sectional view showing a semiconductor device according to this embodiment, and FIG. 2 is an explanatory view about the concentration of light in the semiconductor device shown in FIG. 1. FIGS. 3 and 4 are cross sectional views showing the manufacturing steps for the semiconductor device.

As shown in FIG. 1, a semiconductor device 1 in this embodiment includes a semiconductor substrate 2 so that a light receiving portion 3 is formed on a first surface 2A of the semiconductor substrate 2. The light receiving portion 3 contains light receiving elements such as photodiodes (not shown), for example and configured so as to receive energy beams such as light beams or electron beams to be irradiated onto the first surface 2A. Then, a transistor and a wiring circuit (not shown) are formed on the first surface 2A in addition to the light receiving elements. The transistor and the wiring circuit constitute an active element region.

A plurality of electrodes (not shown) for conducting electric power supply and input/output of electric signal are formed on the first surface 2A so as to be electrically connected with the light receiving portion 3 and the active element region. In this way, the semiconductor device 1 constitutes a so-called image sensor.

Then, an optical transparent protective member 4 with optical transparency is formed on the first surface 2A so as to cover the light receiving portion 3. Also, the optical transparent protective member 4 is provided so as to be adhered with (adjacent to) the first surface 2A with an adhesive (not shown). Since a color filter and/or overcoat layer maybe formed on the first surface 2A as occasion demands, the optical transparent protective member 4 is adhered with the color filter or the like in this case so that the optical transparent protective member 4 is adhered with the first surface 2A via the color filter or the like.

In the present invention, therefore, the phrase “the optical transparent protective member being adhered with the first surface” encompasses the state where the optical transparent protective member 4 is adhered directly with the first surface 2A or the optical transparent protective member 4 is adhered with the first surface 2A via the color filter or the like.

A plurality of depressed portions 5 are formed at the optical transparent protective member 4 through gouging so as to be opposite to the light-receiving portion 3. The depressed portions 5 are also formed corresponding to the light receiving elements such as photodiodes of the light receiving portion 3 as viewed from the plane side. As described above, since the first surface 2A of the semiconductor substrate 2, that is, the light receiving portion 3 is adhered with the optical transparent protective member 4, a space cannot be almost formed between the first surface 2A and the optical transparent protective member 4 except the space relating to the depressed portions 5 formed at the optical transparent protective member 4.

Moreover, through-holes 6 are formed through the thickness of the semiconductor substrate 2 so as to communicate the first surface 2A and a second surface 2B of the semiconductor substrate 2. Then, conductive layers are formed in the corresponding through-holes 6 so that through-wiring layers 7 are formed so as to be electrically connected with the electrodes formed on the first surface 2A. In this embodiment, the through-wiring layers 7 are elongated on the second surface 213. Then, external terminals 9 are formed at the elongated portions of the through-wiring layers 7 on the second surface 2B while a protective layer 8 is formed on the second surface 2B of the semiconductor substrate 2 except the external terminals 9.

In this embodiment, the depressed portions 5 are formed on the side of the optical transparent protective member 4 opposite to the light receiving portion 3 corresponding to the light receiving elements of the light receiving portion 3, and the optical transparent protective member 4 is adhered with the semiconductor substrate 2 such that no space is formed except the space relating to the depressed portions 5 of the optical transparent protective member 4 for the semiconductor substrate 2 (first surface 2A). In this case, the depressed portions 5 function as a microlens array for concentration of light. Moreover, in order to simplify the formation of the through-wiring layers 7 and set the size of the semiconductor device to a size suitable for the CSP, when the semiconductor substrate 2 is thinned, the semiconductor substrate 2 is not bended so as not to cause the creation of crack and thus, enhance the manufacturing yield of the semiconductor device 1 because no space is formed between the optical transparent protective member 4 and the semiconductor substrate 2. Furthermore, since the light receiving portion 3 is not bended, the incident angle of light is not changed within a range of the center to the ends of the light receiving portion 3 so that the imaging characteristic is not deteriorated.

The concentration of light of the semiconductor device 1 in this embodiment is conducted as follows. Namely, as shown in FIG. 2, the light beams incident into the depressed portions 5 are refracted at the interfaces between the depressed portions 5 and the corresponding spaces formed by the depressed portions 5 and the optical transparent protective member 4, and diffused outward. Concretely, the refracted light beams are likely to be concentrated at the areas around the interfaces of the depressed portions 5. Therefore, if the pitch between each of the light receiving elements (not shown) and the corresponding one of the depressed portions 5 is shifted half as large as the pitch one another, the light beams concentrated at the depressed portions 5 can be received at the light receiving elements. As a result, as described above, the depressed portions 5 function as the microlens array for concentration of light.

In this embodiment, moreover, the semiconductor device 1 is electrically connected with the external terminals 9, that is, an external circuit, using the through-wiring layers 7, but may be electrically connected with the external circuit using bonding wires instead of the through-wiring layers 7. In order to downsize the CSP, however, it is desired that the through-wiring layers 7 are employed because an additional area for forming the pads of the bonding wires is not required.

Then, the manufacturing method of the semiconductor device 1 will be described. First of all, as shown in FIG. 3A, a wafer is prepared as the semiconductor substrate 2 such that the light receiving portion 3 containing light receiving elements (not shown) such as photodiodes) and the active element region containing the transistor and wiring circuit (not shown) are formed on the first surface 2A of the semiconductor substrate 2, and the electrodes (not shown) for conducting the input/output of electric signal and the electric power supply are formed on the first surface 2A of the semiconductor substrate 2. The electrodes are electrically connected with the light receiving portion 3 and the active element region. Here, an organic material film such as the color filter may be formed on the main surface, that is, the first surface 2A of the semiconductor substrate 2.

Then, as shown in FIGS. 3B and 3C, the optical transparent protective member 4 with optical transparency and almost the same size as the semiconductor substrate 2 is laminated on the first surface 2A of the semiconductor substrate 2 with an adhesive (not shown). The depressed portions 5 are formed in advance at the surface of the optical transparent protective member 4 opposite to the light receiving portion 3 corresponding to the light receiving elements of the light receiving portion 3 as viewed from the plane side. As a result, a space cannot be almost formed between the first surface 2A and the optical transparent protective member 4 except the space relating to the depressed portions 5 which are formed at the optical transparent protective member 4 through gouging.

The depressed portions 5 are formed by means of dry etching or wet etching using a predetermined mask pattern so as to be shaped in a concave lens form such as a hemispherical lens form or a trapezoidal lens form which are suitable for concentration of light. The optical transparent protective member 4 may be made from borosilicate glass, quartz glass, soda-lime glass or the like. When the optical beams within an infrared wavelength range are transmitted through the optical transparent protective member 4, the optical transparent protective member 4 may be formed from silicon (Si), gallium arsenide (GaAs) or the like.

Then, as shown in FIG. 4A, the semiconductor substrate 2 is thinned from the second surface 2B by means of mechanical grinding, chemical mechanical polishing, wet etching and/or dry etching. The thickness of the thinned semiconductor substrate 2 is desirably set within a range of 50 to 150 μm.

Then, as shown in FIG. 4B, the through-holes 6 are formed through the thickness of the semiconductor substrate 2 so as to communicate the first surface 2A and the second surface 2B. In order to realize the electric connection of the through-wiring layers to be formed later with the electrodes formed on the first surface 2A, in this case, the through-holes 6 are formed so as to partially expose the electrodes formed thereon. The through-holes 6 may be formed by means of plasma etching using a prescribed mask pattern (not shown) from the side of the second surface 2B of the semiconductor substrate 2, for example.

Then, as shown in FIG. 4C, the through-wiring layers 7 are formed so as to embed the through-holes 6 and to be connected internally with the electrodes. In this embodiment, the through-wiring layers 7 are also formed so as to be elongated on the second surface 2B. The through-wiring layers 7 may be formed by means of sputtering, CVD, deposition, plating or printing using a prescribed mask pattern, for example. The through-wiring layers 7 may be made from a high resistance metallic material (Ti, TiN, TiW, Ni, NiV, NiFe, Cr, TaN, CoWP and the like), a low resistance metallic material (Al, Al—Cu, Al—Si—Cu, Cu, Au, Ag, solder and the like), or a conductive resin, for example. A single material may be selected from the listed materials and provided for use. Alternatively, a plurality of materials may be selected from the listed materials and formed in a layered structure.

In this embodiment, since the through-wiring layers 7 are elongated on the second surface 2B of the semiconductor substrate 2, an insulating layer (not shown) is formed in advance such that the electric insulation between the through-wiring layers 7 and the semiconductor substrate 2 can be maintained.

Then, as shown in FIG. 4D, the external terminals 9 are formed on the elongated portions of the through-wiring layers 7 on the second surface 2B of the semiconductor substrate 2 and the protective layer 8 is formed on the second surface 2B except the external terminals 9. The external terminals 9 may be made from a solder material and the protective layer 8 may be made from a polyimide resin, epoxy resin or soldering resist material.

Thereafter, the semiconductor substrate 2 is cut off with the optical transparent protective film 4 by using a cutting blade of a dicer, thereby obtaining the semiconductor device 1 as a chip, as shown in FIG. 1.

### Second Embodiment

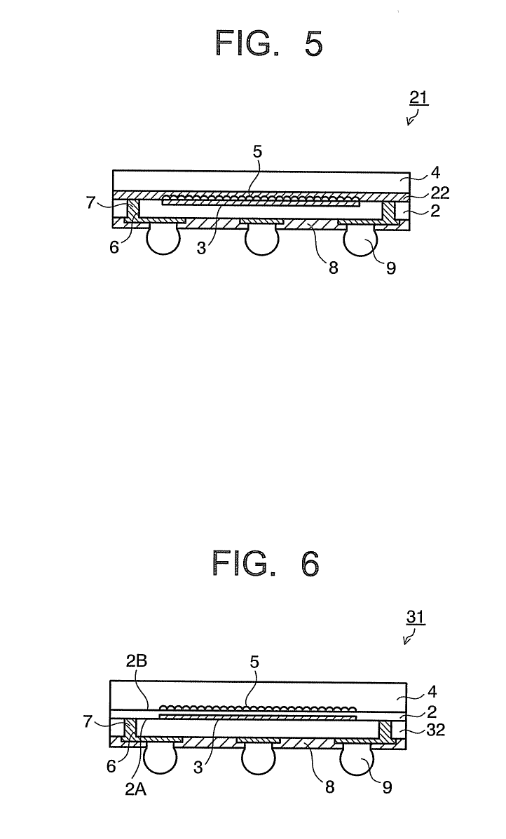

FIG. 5 is a cross sectional view showing a semiconductor device according to this embodiment. In comparison with the first embodiment relating to FIGS. 1 to 4, like or corresponding components are designated by the same reference numerals.

A semiconductor device 21 in this embodiment is configured in component and configuration as the semiconductor device 1 in the first embodiment except that the semiconductor device 21 includes a film 22 between the first surface 2A of the semiconductor substrate 2 and the optical transparent protective member 4 so as to be disposed adjacent to the first surface 2A and the optical transparent protective member 4. Therefore, only the distinctive feature of the semiconductor device 21 will be described and like or corresponding components will not be described, hereinafter.

As described above, the film 22 is disposed between the first surface 2A of the semiconductor substrate 2 and the optical transparent protective member 4 so as to be adjacent to the first surface 2A and the optical transparent protective member 4. For example, the film 22 is adhered with the first surface 2A of the semiconductor 2 with an adhesive (not shown). If the color filter or the overcoat layer is provided on the first surface 2A, the film 22 is fixed to the color filter or the like with the adhesive.

In the present invention, therefore, the phrase “the film being adjacent to the first surface” encompasses the state where the film 22 is adhered directly with the first surface 2A to be adjacent to the first surface 2A or the film 22 is adjacent to the first surface 2A via the color filter or the like.

The plurality of depressed portions 5 are formed in the side of the film 22 opposite to the light receiving portion 3 of the semiconductor substrate 2. In this embodiment, therefore, the depressed portions 5 are formed in advance in the side of the film 22 opposite to the light receiving portion 3 of the semiconductor substrate 2 corresponding to the light receiving elements of the light receiving portion 3, and the film 22 is laminated on the semiconductor substrate 2 (first surface 2A) without space except the space relating to the depressed portions 5. In this case, the depressed portions 5 function as a microlens array for concentration of light. Moreover, in order to simplify the formation of the through-wiring layers 7 and set the size of the semiconductor device to a size suitable for the CSP, when the semiconductor substrate 2 is thinned, the semiconductor substrate 2 is not bended so as not to cause the creation of crack and thus, enhance the manufacturing yield of the semiconductor device 1 because no space is formed between the film 22, the optical transparent protective member 4 and the semiconductor 2 except the space relating to the depressed portions 5. Furthermore, since the light receiving portion 3 is not bended, the incident angle of light is not changed within a range of the center to the ends of the light receiving portion 3 so that the imaging characteristic is not deteriorated.

Furthermore, since the depressed portions 5 are formed at the film 22, the depressed portions 5 can be formed irrespective of the material of the optical transparent protective member 4. Namely, if the film 22 is made from such a material that the depressed portions 5 can be easily formed, the depressed portions 5 can be easily formed and the manufacturing yield can be much enhanced.

It is desired that the refractive index of the film 22 is higher than the refractive index of the optical transparent protective member 4. As described previously, the depressed portions 5 are formed at the film 22 and the space is formed between the depressed portions 5 and the surface of the semiconductor substrate 2, that is, the first surface 2A. The depressed portions 5 function as the microlens array using the space formed therebetween. Since the interior of the space is air, the refractive index of the interior of the space is almost one. Therefore, the depressed portions 5 can exhibit the high concentration of light because the difference in refractive index between the space and the film 22 is increased as the refractive index of the film 22 is increased. On the other hand, if the refractive index of the film 22 is lower than the refractive index of the optical transparent protective member 4, it is desired only in view of the concentration of light that the depressed portions 5 are formed at the optical transparent protective member 4 as an inherent component in comparison that the depressed portions 5 are formed at the film 22 as an additional component.

In this point of view, in order to enhance the concentration of light at the depressed portions 5 in this embodiment, it is desired that the refractive index of the film 22 is higher than the refractive index of the optical transparent protective member 4.

In the case that the optical transparent protective member 4 is made from borosilicate glass, quartz glass, soda-lime glass, for example, the film 22 is made from an organic component such as acrylic-based resin or epoxy-based resin or an inorganic component such as silicon nitride film in order to increase the refractive index of the film 22 than the refractive index of the optical transparent protective member 4. In the case of the use of the organic component, the film 22 may be formed by coating a solution containing the resin listed above. In the case of the use of the inorganic component, the film 22 may be formed by using sputtering method or CVD method.

The depressed portions 5 are formed by means of dry etching or wet etching using a predetermined mask pattern (not shown) so as to be shaped in a concave lens form such as a hemispherical lens form or a trapezoidal lens form which are suitable for concentration of light. When the film 22 is made from a photosensitive organic or inorganic material, or an organic/inorganic hybrid material, the depressed portions 5 can be formed by means of photolithography. Moreover, when the film 22 is made from a photopolymerizable or thermosetting organic material or an organic/inorganic hybrid material, the depressed portions 5 can be formed by means of UV imprint or thermal imprint using a prescribed stamp mask (not shown).

When the optical beams within an infrared wavelength range are transmitted through the optical transparent protective member 4, the optical transparent protective member 4 maybe formed from silicon (Si), gallium arsenide (GaAs) or the like.

Other features in this embodiment are similar to the ones in the first embodiment, and thus, omitted in explanation.

### Third Embodiment

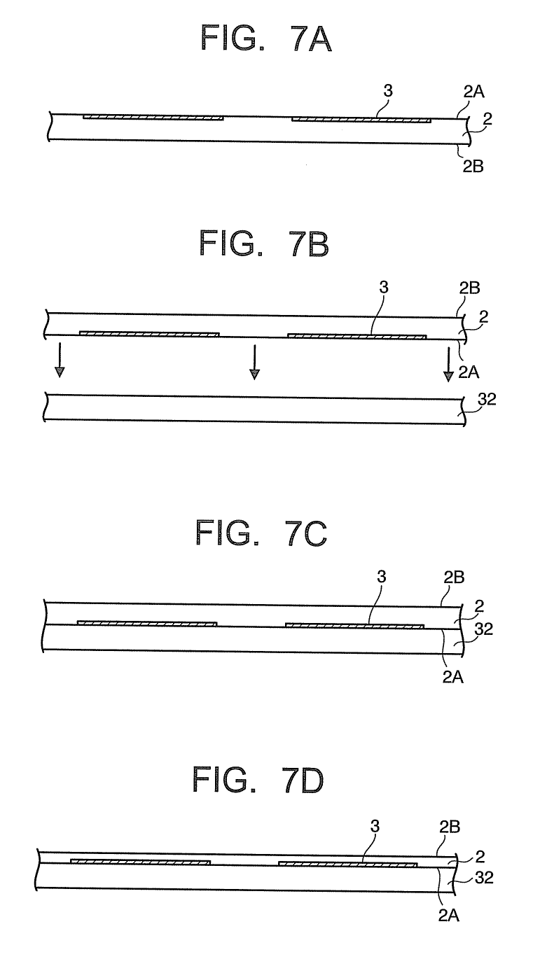

FIG. 6 is a cross sectional view showing a semiconductor device according to this embodiment, and FIGS. 7 to 9 are cross sectional views showing the manufacturing steps for the semiconductor device.

As shown in FIG. 6, a semiconductor device 31 in this embodiment includes a semiconductor substrate 2 so that a light receiving portion 3 is formed on a first surface 2A of the semiconductor substrate 2. The light receiving portion 3 contains light receiving elements such as photodiodes (not shown), for example and configured so as to receive energy beams such as light beams or electron beams to be irradiated onto the first surface 2A. Then, a transistor and a wiring circuit (not shown) are formed on the first surface 2A in addition to the light receiving elements. The transistor and the wiring circuit constitute an active element region.

A plurality of electrodes (not shown) for conducting electric power supply and input/output of electric signal are formed on the first surface 2A so as to be electrically connected with the light receiving portion 3 and the active element region. Then, the semiconductor substrate 2 is thinned and thus, supported by a supporting substrate 32 at the first surface 2A. In this way, the semiconductor device 1 constitutes a so-called backside illuminated image sensor.

In this embodiment, therefore, an optical transparent protective member 4 with optical transparency is formed over the second surface 2B. Also, the optical transparent protective member 4 is provided so as to be adhered with (adjacent to) the second surface 2B with an adhesive (not shown). Since a color filter and/or overcoat layer may be formed on the second surface 2B as occasion demands, the optical transparent protective member 4 is adhered with the color filter or the like in this case so that the optical transparent protective member is adhered with the second surface 2B via the color filter or the like.

In the present invention, therefore, the phrase “the optical transparent protective member being adjacent to the second surface” encompasses the state where the optical transparent protective member 4 is adhered directly with the second surface 2B as described above or the optical transparent protective member 4 is adhered with the second surface 2B via the color filter or the like.

A plurality of depressed portions 5 are formed at the optical transparent protective member 4 so as to be opposite to the light-receiving portion 3 through gouging. The depressed portions 5 are also formed corresponding to the light receiving elements such as photodiodes of the light receiving portion 3 as viewed from the plane side. As described above, since the second surface 2B of the semiconductor substrate 2 is adhered with the optical transparent protective member 4, a space cannot be almost formed between the second surface 2B and the optical transparent protective member 4 except the space relating to the depressed portions 5 formed at the optical transparent protective member 4.

Moreover, through-holes 6 are formed through the thickness of the supporting substrate 32, not the semiconductor substrate 2 in the same manner as the first embodiment. Then, through-wiring layers 7 are formed in the corresponding through-holes 6 so as to be electrically connected with the electrodes formed on the first surface 2A. The through-wiring layers 7 are elongated on the rear surface of the supporting substrate 32. Then, external terminals 9 are formed at the elongated portions of the through-wiring layers 7 on the rear surface of the supporting substrate 32 while a protective layer 8 is formed on the rear surface thereof except the external terminals 9.

In this embodiment, the depressed portions 5 are formed on the side of the optical transparent protective member 4 opposite to the light receiving portion 3 corresponding to the light receiving elements of the light receiving portion 3, and the optical transparent protective member 4 is adhered with the semiconductor substrate 2 such that no space is formed except the space relating to the depressed portions 5 of the optical transparent protective member 4 for the semiconductor substrate 2 (second surface 2B) In this case, if a given load is applied to the semiconductor device 31 or an assembly containing the semiconductor substrate 2, the optical transparent protective member 4 and the supporting substrate 32 under manufacture as will described below, the semiconductor substrate 2 and the supporting substrate 32 are not bended so as not to cause the creation of crack therein and thus, enhance the manufacturing yield of the semiconductor device 31.

In the backside illuminated image sensor, since light to be detected is incident to the second surface 2B, the light is not affected by the active element region. In comparison of the semiconductor device 31 in this embodiment with the semiconductor device 1 in the first embodiment and the semiconductor device 21 in the second embodiment, therefore, the detecting sensitivity of the light can be enhanced. Moreover, it is not required to define the active element region and the light receiving portion 3 on the first surface 2A so that only the active element region can be formed on the first surface 2A. Therefore, the first surface, that is, the semiconductor substrate 2 can be reduced so that the semiconductor device 31 in this embodiment can be downsized.

Then, the manufacturing method of the semiconductor device 31 will be described. First of all, as shown in FIG. 7A, a wafer is prepared as the semiconductor substrate 2 such that the light receiving portion 3 containing light receiving elements (not shown) such as photodiodes) and the active element region containing the transistor and wiring circuit (not shown) are formed on the first surface 2A of the semiconductor substrate 2, and the electrodes (not shown) for conducting the input/output of electric signal and the electric power supply are formed on the first surface 2A of the semiconductor substrate 2. The electrodes are electrically connected with the light receiving portion 3 and the active element region.

Then, as shown in FIGS. 7B and 7C, the supporting substrate 32 with almost the same size as the semiconductor substrate 2 is laminated on the first surface 2A of the semiconductor substrate 2. The lamination of the supporting substrate 32 may be conducted by using an adhesive (not shown) such as epoxy-based resin, polyimide resin, acrylic resin or the like or may be conducted directly by utilizing hydrogen bond or anodic oxidation bond. The supporting substrate 32 may be made from silicon (Si), gallium arsenide (GaAs), borosilicate glass, quartz glass, soda-lime glass, epoxy resin, polyimide resin or the like.

Then, as shown in FIG. 7D, the semiconductor substrate 2 is thinned from the second surface 2B by means of mechanical grinding, chemical mechanical polishing, wet etching and/or dry etching until the energy beams such as light beams or electron beams to be incident onto the second surface 2B of the semiconductor substrate 2 are detected at the light receiving elements (photodiodes) of the light receiving portion 3 on the first surface 2A. With regard to visible light, the thickness of the thinned semiconductor substrate 2 is desirably set within a range of 1 to 20 μm

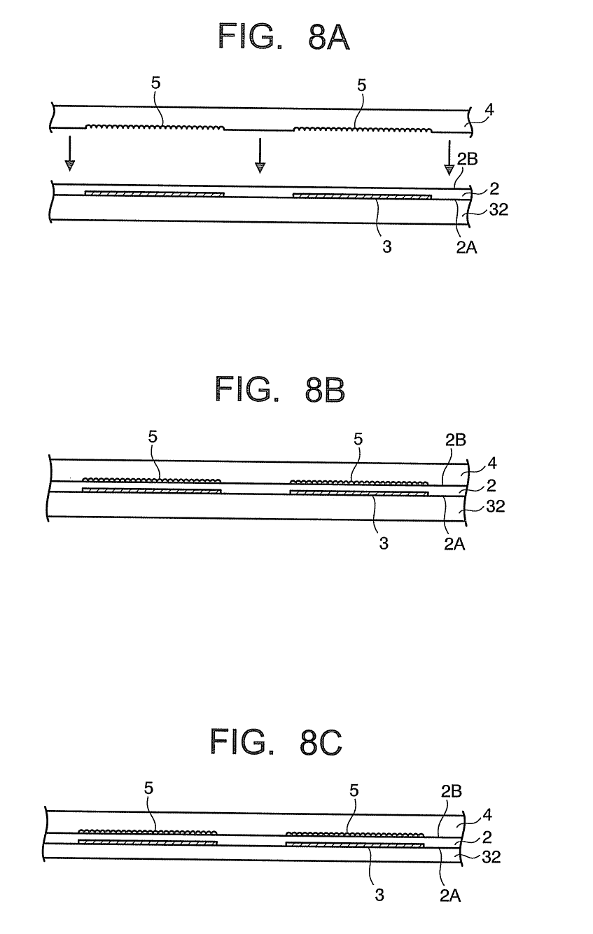

Then, as shown in FIGS. 8A and 8B, the optical transparent protective member 4 with optical transparency and almost the same size as the semiconductor substrate 2 is laminated on the second surface 2A of the semiconductor substrate 2 with an adhesive (not shown). The depressed portions 5 are formed in advance at the surface of the optical transparent protective member 4 opposite to the light receiving portion 3 corresponding to the light receiving elements of the light receiving portion 3 as viewed from the plane side. As a result, a space cannot be almost formed between the second surface 2B and the optical transparent protective member 4 except the space relating to the depressed portions 5 which are formed at the optical transparent protective member 4 through gouging.

The depressed portions 5 are formed by means of dry etching or wet etching using a predetermined mask pattern (not shown) so as to be shaped in a concave lens form such as a hemispherical lens form or a trapezoidal lens form which are suitable for concentration of light. The optical transparent protective member 4 may be made from borosilicate glass, quartz glass, soda-lime glass or the like. When the optical beams within an infrared wavelength range is transmitted through the optical transparent protective member 4, the optical transparent protective member 4 may be formed from silicon (Si), gallium arsenide (GaAs) or the like.

Then, as shown in FIG. 8C, the supporting substrate 32 is thinned from the rear surface thereof by means of mechanical grinding, chemical mechanical polishing, wet etching and/or dry etching. The thickness of the thinned supporting substrate 32 is desirably set within a range of 50 to 150 μm.

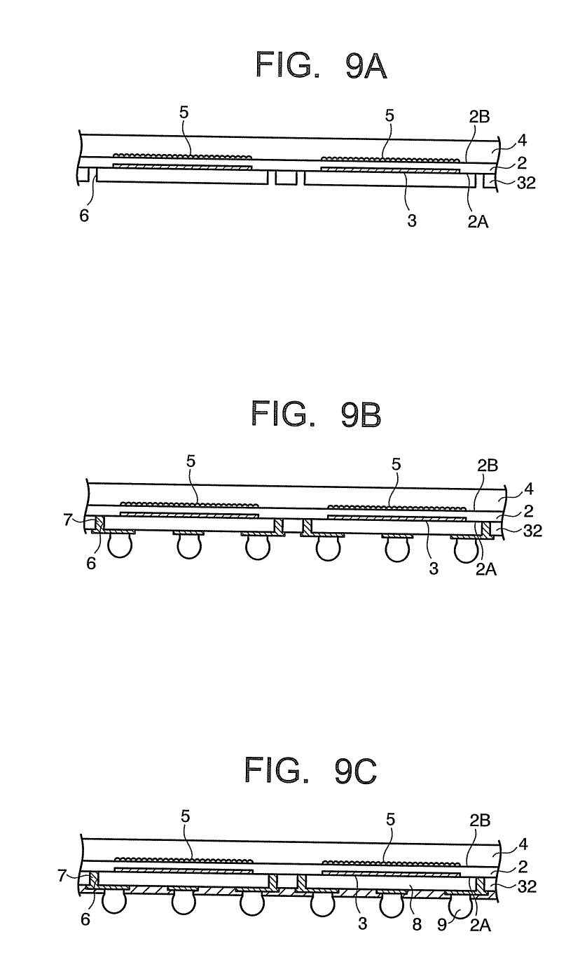

Then, as shorn in FIG. 9A, the through-holes 6 are formed through the thickness of the supporting substrate 32. In order to realize the electric connection of the through-wiring layers to be formed later with the electrodes formed on the first surface 2A, in this case, the through-holes 6 are formed so as to partially expose the electrodes formed thereon. The through-holes 6 may be formed by means of plasma etching using a prescribed mask pattern (not shown) from the side of the rear surface of the supporting substrate 32, for example.

Then, as shown in FIG. 9B, the through-wiring layers 7 are formed, from the rear surface of the supporting substrate 32 so as to embed the through-holes 6 and to be connected internally with the electrodes. In this embodiment, the through-wiring layers 7 are also formed so as to be elongated on the rear surface of the supporting substrate 32. The through-wiring layers 7 may be formed by means of sputtering, CVD, deposition, plating or printing using a prescribed mask pattern, for example. The through-wiring layers 7 may be made from a high resistance metallic material (Ti, TiN, TiW, Ni, NiV, NiFe, Cr, TaN, CoWP and the like), a low resistance metallic material (Al, Al—Cu, Al—Si—Cu, Cu, Au, Ag, solder and the like), or a conductive resin, for example. A single material may be selected from the listed materials and provided for use. Alternatively, a plurality of materials may be selected from the listed materials and formed in a layered structure.

In this embodiment, since the through-wiring layers 7 are elongated on the rear surface of the supporting substrate 32, an insulating layer (not shown) is formed in advance such that the electric insulation between the through-wiring layers 7 and the supporting substrate 32 can be maintained.

Then, as shown in 9C, the external terminals 9 are formed on the elongated portions of the through-wiring layers 7 on the rear surface of the supporting substrate 32 and the protective layer 8 is formed on the rear surface thereof except the external terminals 9. The external terminals 9 may be made from a solder material and the protective layer 8 may be made from a polyimide resin, epoxy resin or soldering resist material.

Thereafter, the semiconductor substrate 2 and the supporting substrate 32 are cut off with the optical transparent protective film 4 by using a cutting blade of a dicer, thereby obtaining the semiconductor device 31 as a semiconductor chip, as shown in FIG. 6.

In this embodiment, the semiconductor device 31 may be electrically connected with the external circuit using bonding wires instead of the through-wiring layers 7.

### Fourth Embodiment

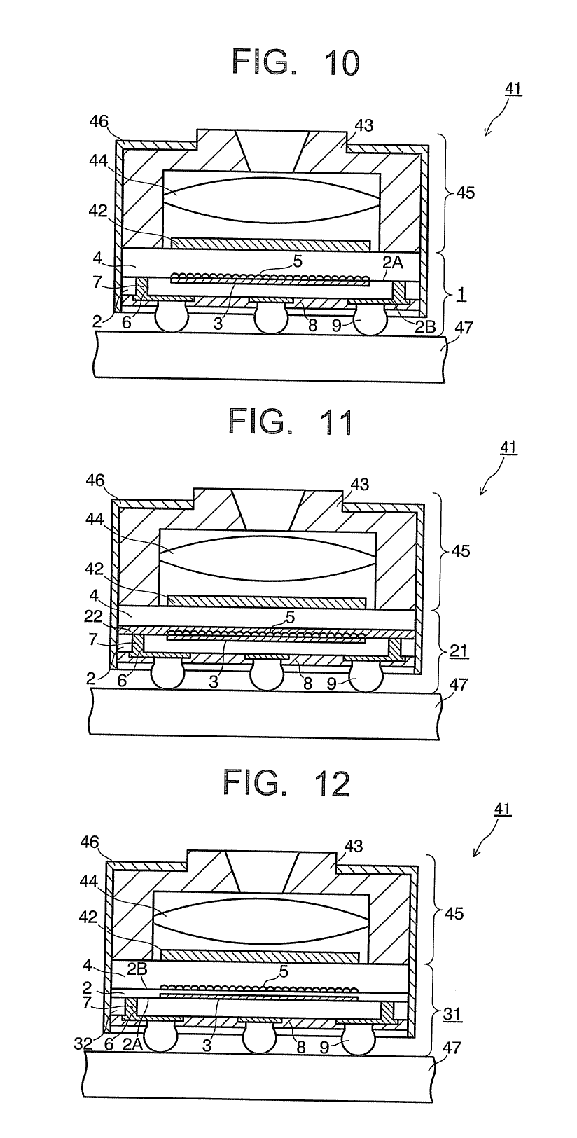

In this embodiment, an imaging device including the semiconductor device according to the first embodiment will be explained. FIG. 10 is a cross sectional view schematically showing a camera module 41 including the semiconductor device 1 mounted thereon according to the first embodiment.

As shown in FIG. 10, since the camera module 41 in this embodiment has the semiconductor device 1 as shown in FIG. 1, the camera module 41 is configured as a so-called BGA (Ball GridArray).

As described above, in the semiconductor device 1, the light receiving portion 3 (e.g., a CCD imaging device or a CMOS imaging device) is formed at the first surface 2A of the semiconductor substrate 2 and covered with the optical transparent protective film 4 (e.g., quartz, borosilicate glass or soda-lime glass) in order to protective the light receiving portion 3 against damage or dust. The depressed portions 5 for concentration of light are provided at the surface of the optical transparent protective film 4 opposite to the light receiving portions 3 so as to function as the microlens array for concentration of light.

An IR (cut) filter 42 is provided on the surface of the optical transparent protective film 4 of the semiconductor device 1. Then, a lens module 45 containing a lens holder 43 and a lens 44 (only one lens 44 is provided in FIG. 10, but a plurality of lenses 44 may be provided) for concentration of light is attached to the area of the optical transparent protective film 4 except the light receiving portion 3 via an adhesive material (not shown). Moreover, the semiconductor device 1 and the lens module 45 are covered with a shield cap 46 (e.g., made of aluminum, SUS or 42 alloy) so as to reinforce the electric shield and the mechanical strength of the camera module 41.

Then, a packaging board 47 with wirings (not shown) is provided at the second surface 2B of the semiconductor device 1 so that the semiconductor device 1 is electrically connected with the packaging board 47 via the through wiring layers 7 and the external terminals 9.

In the camera module 41, the imaging light from an object to be imaged is concentrated through the lens 44, received at the light receiving portion 3, and converted into the corresponding sensor signals through photoelectric conversion. The sensor signals are output and input into a control IC (not shown) formed at an active area (not shown). The control IC includes a digital signal processor which processes the sensor signals to form the corresponding still image or moving image to be output for the packaging board 47 via the through wiring layers 7. The packaging board 47 is connected with a storing device and/or displaying device (not shown) so that the sill image or the moving image is stored in the storing device and/or displayed at the displaying device.

In the camera module 41, if external load is applied to the semiconductor substrate 2 via the external terminals 9 when the semiconductor device 1 is mounted on the packaging board 47, the semiconductor substrate 2 cannot be bended because the depressed portions 5 are formed opposite to the light receiving portions 3 corresponding to the light receiving elements of the light receiving portion 3 and the optical transparent protective member 4 is adhered with the semiconductor substrate 2 without space except the space relating to the depressed portions 5 formed at the semiconductor substrate 2. Therefore, no crack is created at the semiconductor substrate 2 so that the manufacturing yield and mechanical reliability of the camera module 41 can be enhanced.

FIGS. 11 and 12 are cross sectional views relating to the modification of the camera module 41 shown in FIG. 10. Here, like or corresponding components are designated by the same reference numerals. In the camera module 41 shown in FIGS. 11 and 12, the semiconductor device 21 in the second embodiment and the semiconductor device 31 in the third embodiment are mounted, respectively, instead of the semiconductor device 1 in the first embodiment in the camera module 41 shown in FIG. 10. Therefore, the substantial configuration and function/effect of the camera module 41 are not changed from the configuration and function/effect of the camera module 41 relating to the FIG. 10 so as to include the characteristics of the semiconductor device 21 and the semiconductor device 31, respectively.

Namely, if external load is applied to the semiconductor substrate 2 via the external terminals 9 when the semiconductor device 21 or 31 is mounted on the packaging board 47, the semiconductor substrate 2 (and the supporting substrate 32) cannot be bended because the depressed portions 5 are formed opposite to the light receiving portions 3 corresponding to the light receiving elements of the light receiving portion 3 and the optical transparent protective member 4 is adhered with the semiconductor substrate 2 without space except the space relating to the depressed portions 5 formed at the semiconductor substrate 2. Therefore, no crack is created at the semiconductor substrate 2 so that the manufacturing yield and mechanical reliability of the camera module 41 can be enhanced.

Here, the imaging device shown in FIGS. 10 to 12 may be used for a digital camera, a camera cellular phone, an imaging system for electric meeting system or the like.

Although the present invention was described in detail with reference to the above examples, this invention is not limited to the above disclosure and every kind of variation and modification may be made without departing from the scope of the present invention.

What is claimed is:

1. A semiconductor device, comprising:
a semiconductor substrate including a first surface and a second surface which are opposite to one another;
a light receiving portion provided at the first surface of the semiconductor substrate; and
an optical transparent protective member so as to cover and to be adjacent to the first surface or the second surface of the semiconductor substrate;
wherein a plurality of depressed portions are formed at the optical transparent protective member so as to be opposite to the light receiving portion.

2. The semiconductor device as set forth in claim 1,
wherein the optical transparent protective member covers the first surface.

3. The semiconductor device as set forth in claim 2,
wherein the plurality of depressed portions are formed corresponding to light receiving elements of the light receiving portion.

4. The semiconductor device as set forth in claim 3,
wherein a pitch between each of the light receiving elements and the corresponding one of the depressed portions is shifted half as large as the pitch one another.

5. The semiconductor device as set forth in claim 2,
wherein no space is formed between the light receiving portion and the optical transparent protective member except a space relating to the plurality of depressed portions formed at the optical transparent protective member.

6. The semiconductor device as set forth in claim 2, further comprising:
an electrode provided at the first surface of the semiconductor substrate and electrically connected with the light receiving portion and/or an active element region; and
a through wiring layer formed so as to communicate the first surface and the second surface through the semiconductor substrate and electrically connected with the electrode.

7. A semiconductor device, comprising:
a semiconductor substrate including a first surface and a second surface which are opposite to one another;
a light receiving portion provided at the first surface of the semiconductor substrate;
an optical transparent protective member so as to cover the first surface of the semiconductor substrate; and
a film formed between the first surface of the semiconductor substrate and the optical transparent protective member so as to be adjacent to the first surface and the optical transparent protective member;
wherein a plurality of depressed portions are formed at the film so as to be opposite to the light receiving portion.

8. The semiconductor device as set forth in claim 7,
wherein a refractive index of the film is higher than a refractive index of the optical transparent protective member.

9. The semiconductor device as set forth in claim 7,
wherein the plurality of depressed portions are formed corresponding to light receiving elements of the light receiving portion.

10. The semiconductor device as set forth in claim 9,
wherein a pitch between each of the light receiving elements and the corresponding one of the depressed portions is shifted half as large as the pitch one another.

11. The semiconductor device as set forth in claim 7,
wherein no space is formed between the light receiving portion and the optical transparent protective member except a space relating to the plurality of depressed portions formed at the optical transparent protective member.

12. The semiconductor device as set forth in claim 7, further comprising:
an electrode provided at the first surface of the semiconductor substrate and electrically connected with the light receiving portion and/or an active element region; and
a through wiring layer formed so as to communicate the first surface and the second surface through the semiconductor substrate and electrically connected with the electrode.

13. The semiconductor device as set forth in claim 1,
wherein the optical transparent protective member covers the second surface.

14. The semiconductor device as set forth in claim 13,
wherein the plurality of depressed portions are formed corresponding to light receiving elements of the light receiving portion.

15. The semiconductor device as set forth in claim 14,
wherein a pitch between each of the light receiving elements and the corresponding one of the depressed portions is shifted half as large as the pitch one another.

16. The semiconductor device as set forth in claim 13,
wherein no space is formed between the second surface of the semiconductor substrate and the optical transparent protective member except a space relating to the plurality of depressed portions formed at the optical transparent protective member.

17. The semiconductor device as set forth in claim 13, further comprising,
a supporting substrate for supporting the semiconductor substrate at the first surface thereof.

18. The semiconductor device as set forth in claim 17, further comprising:
an electrode provided at a surface of the supporting substrate facing to the first surface of the semiconductor substrate and electrically connected with the light receiving portion and/or an active element region; and
a through wiring layer formed so as to communicate the surface of the supporting substrate and the first surface through the supporting substrate and electrically connected with the electrode.

19. An imaging device, comprising:
a semiconductor device as set forth in claim 7;
a lens module provided on the optical transparent protective member of the semiconductor device; and
a packaging board where the semiconductor device is mounted via external terminals.
